(19) United States
(12) Patent Application Publication
(10) Pub. No.: US 2020/0194200 A1
(43) Pub. Date: Jun. 18, 2020

(54) VACUUM INTERRUPTER LEAK DETECTION USING LOCAL CURRENT AND VOLTAGE MEASUREMENTS

(71) Applicant: S&C Electric Company, Chicago, IL (US)

(72) Inventors: Martin Bishop, Oak Creek, WI (US); Stephen Williams, Caledonia, WI (US); Alejandro Montenegro, Chicago, IL (US)

(73) Assignee: S&C Electric Company, Chicago, IL (US)

(21) Appl. No.: 16/710,061

(22) Filed: Dec. 11, 2019

Related U.S. Application Data
(60) Provisional application No. 62/779,641, filed on Dec. 14, 2018.

(51) Int. Cl. H01H 33/668; G01R 31/327

(52) U.S. Cl. CPC H01H 33/668; G01R 31/3274

(57) ABSTRACT

A method for detecting a vacuum leak in a vacuum interrupter-based switching device. The method monitors current conduction across the contacts when they are open after a predetermined delay. The method detects current conduction across the contacts and adds a current conduction timer unit that accumulates current conduction time to an accumulated total current conduction time value if a magnitude of the detected current conduction exceeds a predetermined current value. The method reduces the accumulated total current conduction time value a certain variable or constant percentage of a predetermined timer value over a settable reset time if current conduction is not detected, and provides an indication if the accumulated total current conduction time value exceeds a predetermined current conduction time threshold.

### CROSS-REFERENCE TO RELATED APPLICATION

This application claims the benefit of priority from the U.S. Provisional Application No. 62/779,641, filed on Dec. 14, 2018, the disclosure of which is hereby expressly incorporated herein by reference for all purposes.

### BACKGROUND

### Field

This disclosure relates generally to a method for detecting a vacuum leak in a vacuum interrupter-based switching device.

### Discussion of the Related Art

An electrical power distribution network, often referred to as an electrical grid, typically includes a number of power generation plants each having a number of power generators, such as gas turbine engines, nuclear reactors, coal-fired generators, hydro-electric dams, etc. The power plants generate a medium voltage that is stepped up to a high voltage AC signal for interconnection to high voltage transmission lines that deliver electrical power to a number of substations typically located within a community, where the voltage is stepped down to a medium voltage. The substations provide the medium voltage power to a number of three-phase feeder lines. The feeder lines are coupled to a number of lateral lines that provide the medium voltage to various transformers, where the voltage is stepped down to a low voltage and is provided to a number of loads, such as homes, businesses, etc.

Power distribution networks of the type referred to above typically include a number of switching devices, circuit breakers, reclosers, interrupters, etc. that both help to control the flow of power throughout the network and interrupt high currents due to short circuit conditions created by faults. A vacuum interrupter is a switching component that has particular application for these types of devices. A vacuum interrupter employs opposing contacts, one fixed and one movable, positioned within an enclosure that maintains a vacuum. The enclosure is commonly referenced as the “bottle,” since it is typically constructed out of a ceramic insulating material. When the interrupter is opened by moving the movable contact away from the fixed contact the arc that is created between the contacts is quickly extinguished due to the vacuum environment. A vapor shield is provided around the contacts to prevent any condensing products produced by the arcing across the contacts from causing a short circuit across the internal surface of the bottle. For certain applications, the vacuum interrupter is encapsulated in a solid insulation housing that either is exposed to the outside weather or may even have a grounded external surface.

Vacuum bottles employed in these types of vacuum interrupter switches typically have a very high dielectric withstand, i.e., a high arc breakdown discharge voltage across the contacts is required to create conduction when the switch is open, provided that the vacuum is maintained in the bottle. If there is a leak in the bottle for any reason and vacuum is reduced, the dielectric withstand voltage level decreases and the applied voltage may be sufficient to result in current conduction across the contacts when they are open, resulting in interrupter switch not operating properly. Should the interrupter switch not operate to according to specification, there can be significant consequences, for example, when the switch is open to clear a high-current fault or opened to keep a part of the circuit de-energized. Specifically, if a fault in the network is detected and a particular interrupter switch upstream of the fault is commanded to open to clear or remove the fault from the system, if that interrupter switch mis-operates, then a next upstream interrupter switch is commanded to open, which unnecessarily prevents power from being provided to some customers between interrupter devices. A longer time is required to clear a fault in this way due to time coordination between the devices.

Devices are known in the art to electrically monitor the level of vacuum in a vacuum interrupter switch. For example, it is known to provide a sensor including a pair of fiber optic cables and a control board, where a loss of vacuum blocks an optical signal propagating on the fiber cables being sent to the control board. However, these known devices typically require a connection through the bottle requiring a seal of the penetration through the bottle wall, thus providing an additional point of vacuum failure. Further, such devices provide additional cost and complexity to the interrupter vacuum switch and have limited reliability. It is desirable to provide a technique for reliably monitoring the status of the vacuum within a vacuum interrupter switch bottle without adding additional components to the switch.

### SUMMARY

The following discussion discloses and describes a method for detecting a vacuum leak in a vacuum interrupter-based switching device. The method includes monitoring for current conduction across contacts in the switching device when they are opened for any reason, where the monitoring starts after a predetermined time delay after opening the switching device. When current conduction is detected through the switching device when the contacts are mechanically opened, i.e., current flow across the open contacts, the method adds the time of current conduction to an accumulated current conduction timer if the magnitude of the detected current exceeds a predetermined current value. The method reduces the accumulated current conduction timer by a certain percentage of a predetermined reset value if the magnitude of the detected current does not exceed a predetermined current value, and sends a signal if the accumulated current conduction timer exceeds a predetermined current conduction time threshold.

In another embodiment for detecting a vacuum leak in a vacuum interrupter-based switching device, the method includes monitoring for current conduction across contacts in the switching device when they are opened for any reason and then measures current conduction across the contacts when they are open. The method also calculates a voltage across the contacts when the current conduction occurs and calculates a power value using the measured current and the calculated voltage. The method compares the power value to a threshold to determine if the power value indicates loss of vacuum in the switching device. Sensor inaccuracies can be compensated for by making the threshold large enough or making the threshold based on a maximum/minimum power ratio from a plurality of switching devices and including a timer in the logic. The voltage can be determined by calculating the voltage by subtracting a voltage measurement provided by a first voltage sensor at one side of the switching device from a voltage measurement provided by a second voltage sensor at an opposite side of the switching device.

In yet another embodiment for detecting a vacuum leak in a vacuum interrupter-based switching device, the method includes monitoring for current conduction across contacts in the switching device when they are opened for any reason and then measures current conduction across a gap between the contacts when they are open. The method also determines a voltage across the contacts when the current conduction occurs and calculates a resistance value using the measured current and the calculated voltage. The method compares the resistance value to a threshold to determine if the resistance value indicates loss of vacuum in the switching device. Sensor inaccuracies can be compensated for by making the threshold based on a maximum/minimum resistance ratio from a plurality of switching devices and including a timer in the logic. The voltage can be determined by calculating the voltage by subtracting a voltage measurement provided by a first voltage sensor at one side of the switching device from a voltage measurement provided by a second voltage sensor at an opposite side of the switching device.

Additional features of the disclosure will become apparent from the following description and appended claims, taken in conjunction with the accompanying drawings.

### BRIEF DESCRIPTION OF THE DRAWINGS

FIG. 1 is an isometric view of a three-phase recloser mounted to a utility pole including three pole units each including a vacuum interrupter;

FIG. 2 is a block diagram of a vacuum interrupter leak detection logic;

FIG. 3 is a flow chart diagram showing a process for determining whether a vacuum interrupter-based switching device has lost vacuum due to a leak in the vacuum enclosure by using a calculated power in the pole units; and

FIG. 4 is a flow chart diagram showing a process for determining whether a vacuum interrupter-based switching device has lost vacuum due to a leak in the vacuum enclosure by using a calculated resistance in the pole units.

### DETAILED DESCRIPTION OF THE EMBODIMENTS

The following discussion of the embodiments of the disclosure directed to a method for detecting a vacuum leak in a vacuum interrupter-based switching device is merely exemplary in nature and is in no way intended to limit the invention or its applications or uses.

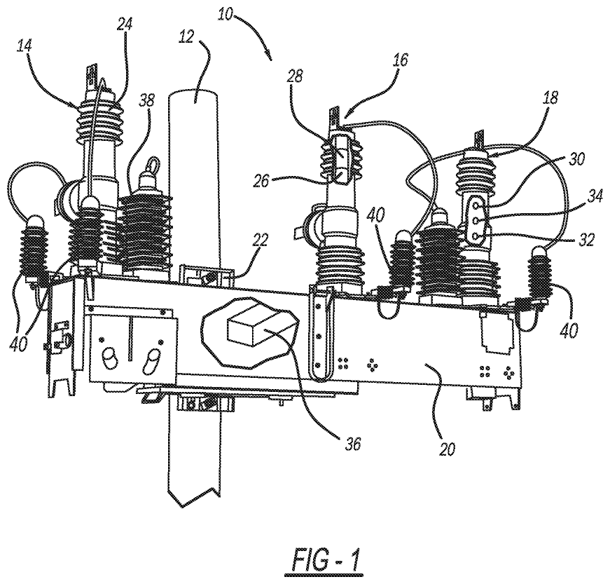

FIG. 1 is an isometric view of a three-phase recloser 10 mounted to a utility pole 12 of a type known in the art. The recloser 10 includes three pole units 14, 16 and 18, one for each phase of a three-phase power line (not shown), mounted to a box-beam base 20, which is secured to the pole 12 by a bracket 22. Each of the pole units 14, 16 and 18 has an outer dielectric housing 24 that encloses a vacuum interrupter-based switching device 26 and associated hardware, where the housing 24 of the pole unit 16 is shown broken away to expose a vacuum bottle 28 associated with the switching device 26 therein. Further, each of the pole units 14, 16 and 18 includes two integrated voltage sensors 30 and 32, one on each side of the switching device 26, and an integrated current sensor 34 that measure the voltage and current flow of each phase of the power line at the recloser location, where the pole unit 18 is shown broken-away to expose the sensors 30, 32 and 34 therein, where details of the sensors 30, 32 and 34 is not shown. The box-beam base 20 houses all of the processors and support hardware that include the algorithms to perform the various operations and logic discussed herein. For example, a controller 36, shown in a broken-away section of the box-beam base 20, processes the voltage and current measurement signals for each phase and controls actuator components that determine the position of the switching device 26, as well as the position of the other poles. A transceiver (not shown) transmits data and messages to a control facility (not shown) and/or to other reclosers and components in the network. A number of integrated power modules 38 are mounted to the box-beam base 20 and operate in a manner well understood by those skilled in the art. Also, surge arresters 40 are mounted to the box-beam base 20 to provide a surge suppression path for the line connections to each pole assembly.

It is noted that although the discussion herein refers to the switching device 26 being part of a pole mounted recloser, it will be understood by those skilled in the art that the discussion below will be applicable for detecting leaks in other types of vacuum interrupter switches, such as, for example, vacuum interrupter switches employed in pad-mounted switchgear, underground switchgear, metal-enclosed switchgear, metal-clad switchgear, air insulated ring main units, wind turbine switchgear, etc.

If the vacuum has been significantly compromised in the vacuum bottle 28 of the switching device 26 there can be current conduction across the vacuum switch contacts when the switching device 26 is open, typically over a fraction or more than a few fundamental frequency AC current cycles depending on the remaining vacuum level in the bottle, the load connected to the circuit and the applied system voltage. The present disclosure describes a method for monitoring current conduction time across the contacts of an open vacuum interrupter to determine if the current conduction is significant enough to indicate that the vacuum bottle of the switching device 26 has lost vacuum. There is a possibility of conduction across the open contacts with a normal vacuum, however, such conduction is typically of very short duration. If a detected current conduction exceeds a certain RMS current magnitude, the time of the current conduction is accumulated with the previous current conduction times, and if the accumulated time reaches a predetermined value, the switching device 26 is identified as being compromised and needs to be replaced. In one non-limiting embodiment, the total time of current conduction occurrence is set at fourteen cycles and if no additional current conduction time is accumulated when the switch is in the open state, then the accumulated time is reduced over thirty days at a linear rate.

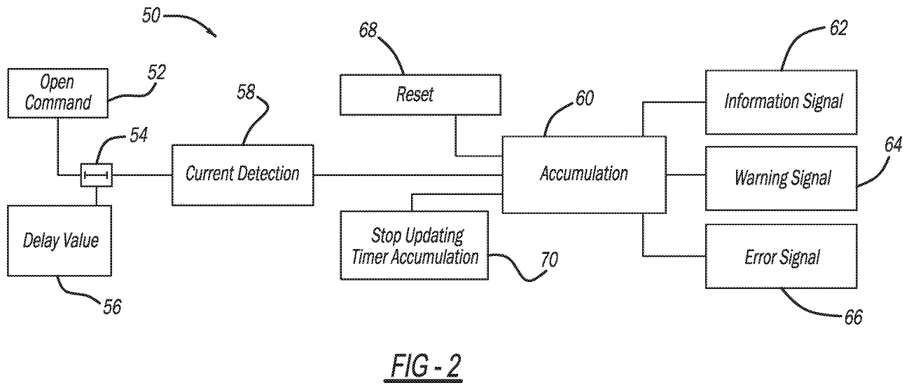

FIG. 2 is a block diagram 50 of a vacuum interrupter switch leak detection logic that provides current conduction monitoring of the switching device 26 as just described that would provide an indication of a condition that indicates loss of vacuum in the switching device 26. At box 52, the switching device 26 is commanded open for some period of time, such as for a system operational condition requiring an open point on a distribution system, which is sent to a delay device 54 that is controlled by a predetermined short delay setting, such as 3-5 current cycles, provided at box 56 so as to give the switching device 26 time to open and the current to be removed therefrom. Once the switching device 26 has been opened and the delay has passed, the current is monitored by the sensor 34 across the open contacts of the switching device 26 at box 58. If the current exceeds a predetermined threshold, such as 2 amps, a signal is sent to an accumulation box 60 to add conduction time value to an already accumulated conduction time value from previous current conduction time when the switching device 26 is commanded to be open. In this non-limiting embodiment, the current conduction time is added to an accumulated time for each current conduction period that exceeds the current threshold setting. The timer applied could be a definite time type or a current-based timer.

Once the accumulated current conduction time reaches a predetermined total threshold time, then the logic sends a signal indicating that the switching device 26 may have lost vacuum and the switching device 26 is compromised. For example, if the recloser 10 is on the utility pole 12, then the signal is transmitted to a control facility using, for example, the supervisory control and data acquisition (SCADA) protocol. In one specific embodiment, when the accumulation of time reaches 40% of the total time threshold an information signal is sent at box 62, when the accumulation of time reaches 80% of the total time threshold a warning signal is sent at box 64, and when the accumulation of time reaches 100% of the total time threshold an error signal is sent at box 66. In addition to providing the signal, in one embodiment a user selection can be provided that actuates closing of the switching mechanism.

If the switching device 26 is open, there still may be some current conduction through the switching device 26 above the threshold that occurs randomly even though the integrity of the vacuum bottle 28 has not been compromised. In this situation, the accumulator in the box 60 may accumulate time from brief current conduction when there is not a problem with the switching device 26. Therefore, the logic diagram 50 includes a reset box 68 that gradually reduces the accumulated time in the accumulation in the box 60 if the detected current conduction periods do not occur frequently enough or for enough of a time duration to indicate a failing switch. Specifically, the reset box 68 reduces the accumulation of time a certain amount if no current conduction is detected during a certain time period. In one example, the reset time could be thirty days so that for each day no current conduction is detected when the switching device 26 is open, the accumulation time is reduced about 3.3%.

The switching device 26 may be closed during normal operation while the leak detection accumulation timer has some accumulated time duration of current conduction but has not reached an information, alarm or error signal time threshold. When the switching device 26 is closed, then current will be detected if a load is connected to the circuit. Since it may be desirable to keep the accumulated time in this situation, so that a failing switch can be detected earlier, the logic diagram 50 stops updating the accumulated time value in the box 60 at box 70 if the switching device 26 is closed before the accumulation reaches the total time needed to set an information, alarm or error signal.

The present disclosure also proposes detecting loss of vacuum in the vacuum bottle 28 of the switching device 26 by observing the power dissipated in the pole units 14, 16 and 18 using the voltage and current measurements from the sensors 30, 32 and 34 when the switching device 26 is open. Particularly, when the switching device 26 in the pole units 14, 16 and 18 is closed, the power dissipated in each pole unit 14, 16 and 18 depends on the current flowing in the switching device 26 due to the downstream load and the total resistance of the switching device 26. When the switching device 26 in the pole units 14, 16 and 18 that has a proper vacuum is open no current should flow between the contacts and the power dissipated should be at or near zero. When the switching device 26 in the pole units 14, 16 and 18 that has lost vacuum is open periodic conduction across the switch contacts generates a substantial amount of power within the switching device 26. Therefore, monitoring the power over a time period in the switching devices 26 of the pole units 14, 16 and 18 when they are open can be used to determine current conduction across the open switch contacts due to loss of vacuum. For example, in order to assess power as a possible loss of vacuum detection mechanism in the switching devices 26, a power calculation can be made using measured voltage and current values from the sensors built into the switching device 26, or even from alternative sensors mounted in close proximity to the switching device 26.

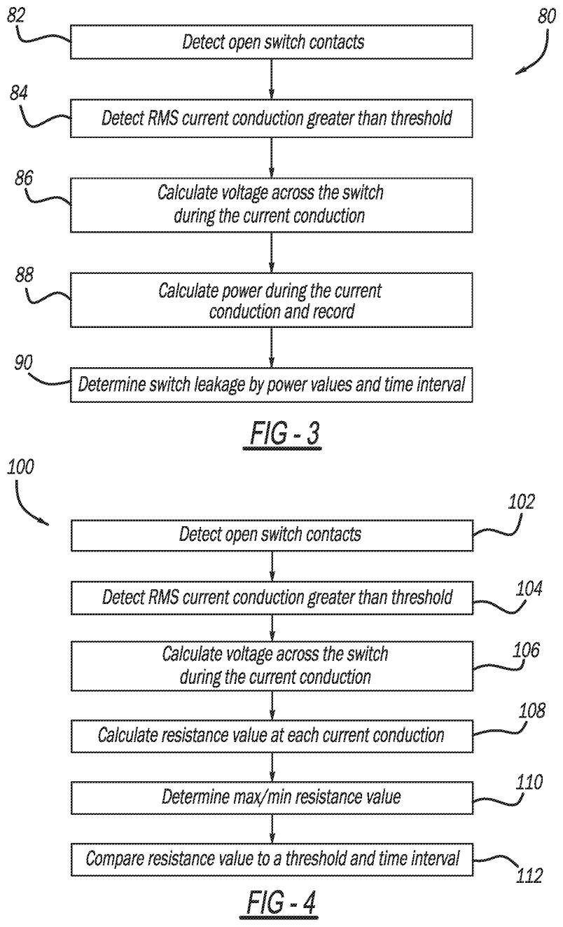

FIG. 3 is a flow chart diagram 80 showing one process for determining whether the switching device 26 has lost vacuum using power dissipation. At box 82, the algorithm determines that the switch contacts have been opened. When the switching device 26 is open, the algorithm measures the current through the switch contacts in each pole unit 14, 16 and 18 continuously by the sensor 34 at box 84 using, for example, a calculation of the root mean square (RMS) current magnitude and phase angle. Typically, such a current conduction period will be a variable depending on the circuit conditions and the state of the vacuum in the switching device 26. The conduction time might be on the order of a half-cycle or longer. For a vacuum interrupter-based switching device having lost vacuum, these current conduction events may also be brief current bursts that are interrupted and re-occur at a later time. The RMS calculation method selected results in a RMS current and phase angle during the conduction period, and also the time that the RMS current magnitude exceeds the selected threshold for each pole unit 14, 6 and 18. As an alternative to using voltage and current magnitude and angle calculations to determine the power by assuming that the current conduction through the open switching device 26 is primarily resistive, the voltage across the open switch contacts can be calculated by subtracting the voltage measurements provided by the voltage sensors 30 and 32 at box 86, and then multiplying the detected current from the sensor 34 by that difference to obtain an estimate of the power dissipated in the pole units 14, 16 and 18 at box 88, where the power for that event for each of the pole units 14, 16 and 18 is recorded.

An expected power loss across a vacuum interrupter-based switching device with appropriate contact pressure and rated current is approximately 10-15 watts. A practical switching device designed to meet industry requirements will have sensor errors that skew the conclusions of the condition of the pole units 14, 16 and 18, i.e., the pole units 14, 16 and 18 may have unexpected power levels due to the reported current in addition to voltage sensor tolerances. Current magnitude and phase angle reported by the pole units 14, 16 and 18 are also subject to errors in the derivation of RMS amperes in the control algorithm. In order to overcome measurement errors the process will also compare, at box 90, the calculated power values at a predetermined qualification time in each of the pole units 14, 16 and 18 to each other. In one example, a ratio of the maximum to the minimum measured values from the three poles in a switch, and to a predetermined threshold, with both measured values exceeding a threshold over a predetermined time interval, can be used to identify a failing switch, and a suitable warning can be given. Comparison of the results across the pole units 14, 16 and 18 over a time interval yields a better indication of interrupter switch leakage under the assumption that it is unlikely that all three of the switching device 26 would lose vacuum at the same time.

The present disclosure also proposes detecting loss of vacuum in the switching device 26 by observing the resistance of the switching devices 26 in each of the pole units 14, 16 and 18 using the voltage and current measured by the sensors 30, 32 and 34, where the resistance is determined by the difference in the voltage across the switching device 26 when it is open divided by the measured current. FIG. 4 is a flow chart diagram 100 showing one process for determining whether the switching device 26 has lost vacuum using resistance measurements. At box 102, the algorithm determines that the switch contacts have been opened. When the switching device 26 is open, the algorithm measures the current through the switch contacts in each pole unit 14, 16 and 18 continuously by the sensor 34 at box 104 using, for example, a calculation of the RMS current magnitude and phase angle. Typically, such a current conduction period will be a variable depending on the circuit conditions and the state of the vacuum in the switching device 26. The conduction time might be on the order of a half-cycle or longer. For a vacuum interrupter-based switching device having lost vacuum, these current conduction events may also be brief current bursts that are interrupted and re-occur at a later time. As an alternative to using voltage and current magnitude and angle calculations, by assuming that the current conduction through the switching device 26 is primarily resistive, the voltage across the open switch contacts can be calculated by subtracting the voltage measurements provided by the voltage sensors 30 and 32 at box 106, and then dividing that voltage by the detected current from the sensor 34 to obtain an estimate of the resistance in the pole units 14, 16 and 18 at box 108, where the resistance for that event for each of the pole units 14, 16 and 18 is recorded.

A normally closed vacuum interrupter-based switching device should have a resistance between 30-50 μΩ. When the switching device 26 is open, the resistance should be infinite, i.e., zero amps in the denominator of the voltage/current calculation. However, the resistance values calculated in an opening device also includes the sensor accuracy issue referred to above in the calculations performed for an open vacuum interrupter-based switching device, and thus these values may not be known to a high enough confidence to conclude that the switching device 26 is in a failed state based on a single pole measurement using available measurements.

A technique can be implemented to remove the sensor inaccuracy in this embodiment for determining loss of vacuum in the switching device 26 by dividing the maximum resistance by the minimum resistance for the three pole units 14, 16 and 18 at each current conduction occurrence at box 110, and recording the value. For a normal switch load current with a properly operating vacuum interrupter-based switching device, a ratio of Max/Min resistance value should be a reasonably low multiple. For switches that have lost vacuum a suitable Max/Min threshold value could be 100. This would mean that any variance between the observed resistance between the maximum and the minimum of the three resistance values from the three-pole unit 14, 16 and 18 should be less than 100. The algorithm compares the calculated Max/Min resistance values to the threshold at box 112 to determine if the switching device 26 may have lost vacuum. A suitable warning can be given if the resistance value exceeds the threshold over some predetermined number of sample times and a predetermined time interval.

The embodiment discussed above uses the voltage and current measurements from the sensors 30, 32 and 34 to determine the resistance values that are then used to determine if a vacuum interrupter has lost vacuum in a pole unit. However, other embodiments may employ different techniques for determining the resistance of the pole units 14, 16 and 18 for this purpose. For example, a current supervised impedance/resistance relay element built as software operating in the controller 36 can be employed in the pole units 14, 16 and 18 to measure impedance from the current conducting conditions in the switching device 26, and those impedance values can be compared to known impedance values for a proper operating switch to determine loss of vacuum from observed current conduction when the switching device 26 is open.

In one of the herein disclosed embodiments, a method for detecting a vacuum leak in a vacuum interrupter-based switching device may include detecting current conduction when contacts of the switching device are open after a predetermined delay, adding a current conduction timer unit that accumulates current conduction time to an accumulated total current conduction time value if a magnitude of the detected current conduction exceeds a predetermined current conduction value; and sending a signal if the accumulated total current conduction time value exceeds a predetermined current conduction timer threshold.

The method may further include sending an information, alarm or error signal depending on the accumulated total current conduction time value. Alternatively, the method may include reducing the accumulated total current conduction time value a variable or fixed amount of a predetermined timer value over a settable reset time value if current conduction is not detected when the contacts are open. In a further alternative, the method may include stopping any timer update and preserving the accumulated total current conduction time value if the contacts are closed. In still a further alternative embodiment, the method may include sending information signal if the accumulated total current conduction time value reaches 40% of the predetermined current conduction timer threshold, sending a warning signal if the accumulated total current conduction time value reaches 80% of the predetermined current conduction timer threshold, and sending an error signal if the accumulated total current conduction time value reaches 100% of the predetermined current conduction timer threshold. In yet another embodiment,

In another of the herein described embodiments, a method for detecting a vacuum leak in a vacuum interrupter-based switching device may include monitoring for current conduction when contacts of the switching device are open after a predetermined delay; adding a current conduction timer unit that accumulates current conduction time to an accumulated total current conduction time value if a magnitude of the detected current conduction exceeds a predetermined current conduction value; reducing the accumulated total current conduction time value a certain percentage of a predetermined timer value over a settable reset time value if current conduction is not detected; and sending a signal if the accumulated total current conduction time value exceeds a predetermined current conduction timer threshold.

The method may further include sending the signal if the accumulated total current conduction time value exceeds fourteen fundamental frequency current cycles for a 60 Hz power system, and wherein the accumulated total current conduction time value may be reduced by a prorated equal percentage of 10 days or 30 days for each day current conduction is not detected when the contacts are open. The method may alternatively include storing and saving the accumulated total current conduction time value if the contacts are closed. In yet another embodiment, the method may further include sending an information signal if the accumulated total current conduction time value reaches 40% of the predetermined current conduction timer threshold, sending a warning signal if the accumulated total current conduction time value reaches 80% of the predetermined current conduction timer threshold, and sending an error signal if the accumulated total current conduction time value reaches 100% of the predetermined current conduction timer threshold. In still an further alternative embodiment, the predetermined current conduction value is 2 amperes root mean square (RMS) at fundamental frequency. In another embodiment the vacuum interrupter-based switching device may be part of a pole unit associated with a recloser.

In another of the herein described embodiments, a system for detecting a vacuum leak in a vacuum interrupter-based switching device may include means for monitoring for current conduction when contacts of the switching device are open after a predetermined delay; means for adding a current conduction timer unit that accumulates current conduction time to an accumulated total current conduction time value if a magnitude of the detected current conduction exceeds a predetermined current conduction value; means for reducing the accumulated total current conduction time value a certain percentage of a predetermined timer value over a settable reset time value if current conduction is not detected; and means for sending a signal if the accumulated total current conduction time value exceeds a predetermined current conduction timer threshold. The system may further include storing and saving the accumulated total current conduction time value if the contacts are closed. Alternatively, the means for sending a signal sends an information signal if the accumulated total current conduction time value reaches 40% of the predetermined current conduction timer threshold, may send a warning signal if the accumulated total current conduction time value reaches 80% of the predetermined current conduction timer threshold, and sends an error signal if the accumulated total current conduction time value reaches 100% of the predetermined current conduction timer threshold. Alternatively, the means for sending a signal may send an information, alarm or error signal depending on the accumulated total current conduction time value. In still further alternative the means for reducing the accumulated total current conduction time value reduces a variable or fixed amount of a predetermined timer value over a settable reset time value if current conduction is not detected when the contacts are open.

In yet another alternative embodiment, a method for detecting a vacuum leak in a vacuum interrupter-based switching device may include measuring current conduction across contacts of the switching device when they are open; determining a voltage across the switching device when the current conduction occurs; calculating a power value using the measured current and the calculated voltage; and comparing the power value to a power threshold to determine if the power value indicates loss of vacuum in the switching device. In this embodiment, measuring current conduction may include calculating a root mean square (RMS) current magnitude and phase angle value, which may include that the RMS current magnitude and phase angle value is calculated over the current conduction time. In another embodiment, determining a voltage may include calculating the voltage by subtracting a voltage measurement provided by a first voltage sensor at one side of the switching device from a voltage measurement provided by a second voltage sensor at an opposite side of the switching device. In still another embodiment, determining a voltage may include measuring the voltage. In yet an alternative embodiment, comparing the calculated power value to a threshold may include making the power threshold well above an expected power in the switching device so as to compensate for current and voltage sensor inaccuracies. In still another alternative embodiment, the method may include providing a warning signal if the power value exceeds the power threshold for a predetermined time interval. In a further alternative embodiment, comparing the power value may include comparing the power value to a calculated power value of at least one other vacuum interrupter-based switching device, wherein the number of vacuum interrupter-based switching devices is three and further wherein the vacuum interrupter-based switching devices are part of a pole unit associated with a pole mounted recloser.

In another of the herein described embodiment, a method for detecting a vacuum leak in a vacuum interrupter-based switching device that is in each of three pole units associated with a three-phase pole mounted recloser, may include measuring current conduction across contacts of the switching device when they are open; calculating a voltage across the switching devices when the current conduction occurs by subtracting a voltage measurement provided by a first voltage sensor at one side of the switching device from a voltage measurement provided by a second voltage sensor at an opposite side of the switching device; calculating a power value for each switching device using the measured current and the calculated voltage; and comparing the calculated power values to a power threshold and to each other for the three-phase pole units of the switching devices to determine if the power value indicates loss of vacuum in any one of the pole units. In an alternative embodiment measuring current conduction includes calculating a root mean square (RMS) current magnitude and phase angle value at fundamental frequency, and wherein further the RMS current magnitude and phase angle value is calculated over a current conduction time interval. In yet another alternative embodiment, comparing the power value to a threshold may include making the threshold well above an expected power in the switching device so as to compensate for current and voltage sensor inaccuracies. In still another alternative embodiment, the method may include providing a warning signal if the power value exceeds the power threshold for a predetermined number time interval.

In another of the herein described embodiments, a system for detecting a vacuum leak in a vacuum interrupter-based switching device, the system may include means for measuring current conduction across contacts of the switching device when they are open; means for determining a voltage across the switching device when the current conduction occurs; means for calculating a power value using the measured current conduction and the calculated voltage; and means for comparing the power value to a power threshold to determine if the power value indicates loss of vacuum in the switching device. In alternative embodiments, the means for measuring current conduction may calculate a root mean square (RMS) current magnitude and phase angle value, wherein the RMS current magnitude and phase angle value is calculated over the current conduction time. In still further alternative embodiments, the means for determining a voltage calculates the voltage by subtracting a voltage measurement provided by a first voltage sensor at one side of the switching device from a voltage measurement provided by a second voltage sensor at an opposite side of the switching device. In still a further embodiment, the means for determining a voltage measures the voltage.

In accordance with still additional herein described embodiments, method for detecting a vacuum leak in a vacuum interrupter-based switching device may include measuring current conduction across contacts of the switching device when they are open; determining a voltage across the switching device when the current conduction occurs; calculating a resistance value using the measured current and the calculated voltage; and comparing the resistance value to a threshold to determine if the resistance value indicates loss of vacuum in the switching device. In another embodiment, measuring a current conduction may include calculating a root mean square (RMS) current magnitude and phase angle value at fundamental frequency, and wherein the RMS current magnitude and phase angle value may be calculated over a current conduction time interval. In still another embodiment, a voltage may include calculating the voltage by subtracting a voltage measurement provided by a first voltage sensor at one side of the switching device from a voltage measurement provided by a second voltage sensor at an opposite side of the switching device, wherein determining a voltage includes measuring the voltage. In still another embodiment, the method may further include determining a resistance value of a plurality of vacuum interrupter-based switching devices using voltage and current during a current conduction time interval and determining a maximum/minimum resistance ratio value from the calculated resistances at certain sample points, wherein comparing the resistance value to a threshold includes using the resistance ratio value to determine the threshold so as to compensate for sensor inaccuracies, wherein the plurality of vacuum interrupter-based switching devices may be three vacuum interrupter-based switching devices and wherein the vacuum interrupter-based switching devices may be part of a pole unit associated with a pole mounted recloser. In another embodiment, the method may further comprise providing a warning signal concerning a vacuum interrupter leak if the resistance value exceeds the threshold for a predetermined time interval. In still another embodiment, the threshold may be 100.

In another of the herein described embodiments, a method for detecting a vacuum leak in a vacuum interrupter-based switching device may include detecting current conduction across contacts of the switching device when they are open; determining a resistance value of the switching device during the current conduction; and comparing the resistance value to a threshold to determine if the resistance value indicates loss of vacuum in the switching device. In another embodiment, determining a resistance value may include calculating the resistance value from a measured current through the switching device and a calculated voltage across the switching device, wherein determining a resistance value may include determining an impedance value and determining an impedance value may include using a supervised impedance/resistance relay element.

In still a further herein described embodiment, a method for detecting a vacuum leak in each vacuum interrupter-based switching device that is in each of three pole units associated with a pole mounted recloser may include: measuring current conduction across contacts of the switching device when they are open; calculating a voltage across the switching devices when the current conduction occurs by subtracting a voltage measurement provided by a first voltage sensor at one side of the switching device from a voltage measurement provided by a second voltage sensor at an opposite side of the switching device; calculating a resistance value for each switching device using an impedance element, the measured current and the calculated voltage; and comparing the calculated resistance values to a threshold to determine if the resistance value indicates loss of vacuum in any of the switching devices. In alternative embodiments, measuring a current conduction includes calculating a root mean square (RMS) current magnitude and phase angle value, wherein the RMS current magnitude and phase angle value may be calculated over a current conduction time interval. In an alternative embodiment, a maximum/minimum resistance ratio value is determined from the calculated resistances at certain sample points, and comparing the resistance value to a threshold may include using the resistance ratio to determine the threshold so as to compensate for sensor inaccuracies, wherein the threshold may be 100. In yet another embodiment, the method may include providing a warning signal concerning a vacuum interrupter leak if the resistance value exceeds the threshold for a predetermined time interval.

The foregoing discussion discloses and describes merely exemplary embodiments of the present disclosure. One skilled in the art will readily recognize from such discussion and from the accompanying drawings and claims that various changes, modifications and variations can be made therein without departing from the spirit and scope of the disclosure as defined in the following claims.

What is claimed is:

1. A method for detecting a vacuum leak in a vacuum interrupter-based switching device, said method comprising:
detecting current conduction when contacts of the switching device are open after a predetermined delay;
adding a current conduction timer unit that accumulates current conduction time to an accumulated total current conduction time value if a magnitude of the detected current conduction exceeds a predetermined current conduction value; and
sending a signal if the accumulated total current conduction time value exceeds a predetermined current conduction timer threshold.

2. The method according to claim 1 wherein sending a signal includes sending an information, alarm or error signal depending on the accumulated total current conduction time value.

3. The method according to claim 1 further comprising reducing the accumulated total current conduction time value a variable or fixed amount of a predetermined timer value over a settable reset time value if current conduction is not detected when the contacts are open.

4. The method according to claim 1 further comprising stopping any timer update and preserving the accumulated total current conduction time value if the contacts are closed.

5. The method according to claim 1 wherein sending a signal includes sending an information signal if the accumulated total current conduction time value reaches 40% of the predetermined current conduction timer threshold, sending a warning signal if the accumulated total current conduction time value reaches 80% of the predetermined current conduction timer threshold, and sending an error signal if the accumulated total current conduction time value reaches 100% of the predetermined current conduction timer threshold.

6. The method according to claim 1 wherein the predetermined current conduction value is the smallest current that can be reliably measured within a resolution of the switching device.

7. The method according to claim 6 wherein the predetermined current conduction value is 2 amperes root mean square (RMS) at fundamental frequency.

8. The method according to claim 1 further comprising storing and saving the accumulated total current conduction time value if the contacts are closed.

9. A method for detecting a vacuum leak in a vacuum interrupter-based switching device, said method comprising:
measuring current conduction across contacts of the switching device when they are open;
determining a voltage across the switching device when the current conduction occurs;
calculating a power value using the measured current and the calculated voltage; and
comparing the power value to a power threshold to determine if the power value indicates loss of vacuum in the switching device.

10. The method according to claim 9 wherein measuring current conduction includes calculating a root mean square (RMS) current magnitude and phase angle value.

11. The method according to claim 10 wherein the RMS current magnitude and phase angle value is calculated over the current conduction time.

12. The method according to claim 9 wherein determining a voltage includes calculating the voltage by subtracting a voltage measurement provided by a first voltage sensor at one side of the switching device from a voltage measurement provided by a second voltage sensor at an opposite side of the switching device.

13. The method according to claim 9 wherein determining a voltage includes measuring the voltage.

14. The method according to claim 9 wherein comparing the calculated power value to a threshold includes making the power threshold well above an expected power in the switching device so as to compensate for current and voltage sensor inaccuracies.

15. The method according to claim 9 further comprising providing a warning signal if the power value exceeds the power threshold for a predetermined time interval.

16. The method according to claim 9 wherein comparing the power value includes comparing the power value to a calculated power value of at least one other vacuum interrupter-based switching device.

17. A method for detecting a vacuum leak in a vacuum interrupter-based switching device, said method comprising:
measuring current conduction across contacts of the switching device when they are open;
determining a voltage across the switching device when the current conduction occurs;
calculating a resistance value using the measured current and the calculated voltage; and
comparing the resistance value to a threshold to determine if the resistance value indicates loss of vacuum in the switching device.

18. The method according to claim 17 wherein measuring a current conduction includes calculating a root mean square (RMS) current magnitude and phase angle value at fundamental frequency.

19. The method according to claim 18 wherein the RMS current magnitude and phase angle value is calculated over a current conduction time interval.

20. The method according to claim 17 wherein determining a voltage includes calculating the voltage by subtracting a voltage measurement provided by a first voltage sensor at one side of the switching device from a voltage measurement provided by a second voltage sensor at an opposite side of the switching device.

21. The method according to claim 17 wherein determining a voltage includes measuring the voltage.

22. The method according to claim 17 further comprising determining a resistance value of a plurality of vacuum interrupter-based switching devices using voltage and current during a current conduction time interval and determining a maximum/minimum resistance ratio value from the calculated resistances at certain sample points, wherein comparing the resistance value to a threshold includes using the resistance ratio value to determine the threshold so as to compensate for sensor inaccuracies.

23. The method according to claim 17 further comprising providing a warning signal concerning a vacuum interrupter leak if the resistance value exceeds the threshold for a predetermined time interval.

24. The method according to claim 17 wherein the threshold is 100.
